(19) United States
(12) Patent Application Publication
(10) Pub. No.: US 2026/0351311 A1
(43) Pub. Date: Nov. 5, 2026

(54) METHODS OF MANUFACTURE TO MITIGATE SURFACE MOUNT TECHNOLOGY (SMT) IMPACT ON BIT ERROR RATE (BER) OF RESISTIVE RANDOM ACCESS MEMORY (RERAM) CELLS BY ADAPTATION OF RESISTANCE THRESHOLD

(71) Applicant: Weebit Nano Ltd., Hod Hasharon (IL)

(72) Inventors: Giuseppe PICCOLBONI, Grenoble (FR); Gabriel MOLAS, Fontanil (FR)

(73) Assignee: Weebit Nano Ltd., Hod Hasharon (IL)

(21) Appl. No.: 19/715,182

(22) Filed: Jun. 22, 2026

Related U.S. Application Data
(63) Continuation of application No. PCT/IB2023/000770, filed on Dec. 22, 2023.

(51) Int. Cl. G11C 13/00; H05K 1/181; H05K 3/303

(52) U.S. Cl. CPC G11C 13/0033; G11C 13/0069; H05K 1/181; H05K 3/303; G11C 2013/0083; H05K 2201/10159

(57) ABSTRACT

As surface mount technology (SMT) process can have a significant impact on the bit error rate (BER) of resistive random-access memory (ReRAM) devices there is provided a manufacturing process to mitigate the impact. Specifically, when mounting a ReRAM device on a printed circuit board (PCB) using SMT the BER increases. Accordingly, a method adds a step of reading the ReRAM device's cells with an optimized resistive threshold value that improves the BER, the optimized resistance selected from a SMT reference resistance bank. Thereafter, a refresh cycle of the ReRAM devices is performed at nominal resistive value. Adapting the resistive threshold for reading post-SMT reduces BER enough for an error correction mechanism to salvage the chip because of the BER's less dramatic degradation. Also disclosed are a ReRAM device and a system for BER degradation mitigation upon mounting of a ReRAM device on a PCB using SMT.

### CROSS-REFERENCE TO RELATED APPLICATIONS

This application is a continuation of International Application No. PCT/IB2023/000770 filed on Dec. 22, 2023, the contents of which are hereby incorporated by reference.

### TECHNICAL FIELD

The present disclosure generally relates to resistive random-access memory (ReRAM) cells, and more particularly to an improvement in manufacturing process to mitigate bit error rate (BER) increase at surface mount technology (SMT) used in conjunction with ReRAM devices.

### BACKGROUND

The surface mount technology (SMT) process can have a significant impact on the bit error rate (BER) of resistive random-access memory (ReRAM) devices. In SMT, electrical and electronic components are mounted directly onto a printed circuit board (PCB) without a need to use through-hole technology that has holes going through the PCB. The BER is a measure of the number of bit errors, indicating the accuracy of data storage and retrieval in the memory device. The lower the number, the better the performance of the device.

In a typical manufacturing process, the ReRAM device is initialized by the manufacturer of the device according to requirements. Then, typically, another entity, who purchased the ReRAM devices, manufactures a PCB that has therein various components including the ReRAM devices. However, the impact of the SMT manufacturing step results in degradation of the performance of the ReRAM devices, and more specifically, the BER increases, i.e., there are more bit errors. Typically, a ReRAM device may be equipped with some kind of error correction capabilities, however, as BER increases, it becomes less likely that the error correction used can overcome the impact of the BER increase.

The reasons for the impact of SMT on the ReRAM device are several and include thermal stress, contamination and oxidation, defect formation, and mechanical handling. Specifically, high temperatures associated with the SMT reflow may cause a resistance change of the ReRAM and loss of the memory state. Regardless of the particular reason for such an impact, it is advantageous to find a manufacturing process that can mitigate in full or to an extent the impact of the SMT manufacturing step.

### SUMMARY

A summary of several example embodiments of the disclosure follows. This summary is provided for the convenience of the reader to provide a basic understanding of such embodiments and does not wholly define the breadth of the disclosure. This summary is not an extensive overview of all contemplated embodiments and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “some embodiments” or “certain embodiments” may be used herein to refer to a single embodiment or multiple embodiments of the disclosure.

Certain embodiments disclosed herein include a method for mitigation of bit error rate (BER) increase from surface mount technology (SMT) used to mount a resistive random-access memory (ReRAM) device onto a printed circuit board (PCB), the method comprising: mounting the ReRAM device to the PCB using SMT, wherein the ReRAM device comprises a plurality of ReRAM cells; selecting a SMT reference resistance of the ReRAM device, wherein the SMT reference resistance is higher than a pre-SMT reference resistance; and performing at least one read operation on at least one of the plurality of ReRAM cells using the selected SMT reference resistance as a reference.

Certain embodiments disclosed herein also include a non-transitory computer readable medium having stored thereon instructions for causing a processing circuitry to execute a process for mitigation of bit error rate (BER) increase from surface mount technology (SMT) used to mount a resistive random-access memory (ReRAM) device onto a printed circuit board (PCB), the process comprising: mounting the ReRAM device to the PCB using SMT, wherein the ReRAM device comprises a plurality of ReRAM cells; selecting a SMT reference resistance of the ReRAM device, wherein the SMT reference resistance is higher than a pre-SMT reference resistance; and performing at least one read operation on at least one the plurality of ReRAM cells using the selected SMT reference resistance as a reference.

Furthermore, certain embodiments disclosed herein also include a system for mitigation of bit error rate (BER) increase from surface mount technology (SMT) used to mount at least one resistive random-access memory (ReRAM) devices onto a printed circuit board (PCB), the system comprising: a connectivity network; a device under test (DUT) comprising the PCB with the at least one ReRAM devices; a processing circuitry communicatively connected to the connectivity network; and a memory, the memory containing instructions that, when executed by the processing circuitry, configure the system to: mount the ReRAM device to the PCB using SMT, wherein the at least one ReRAM device comprises a plurality of ReRAM cells; select a SMT reference resistance of the ReRAM device, wherein the SMT reference resistance is higher than a pre-SMT reference resistance; and perform at least one read operation on at least one of the plurality of ReRAM cells using the selected SMT reference resistance as a reference.

Yet other embodiments disclosed herein also include a resistive random-access memory (ReRAM) device for mitigation of bit error rate (BER) increase from surface mount technology (SMT) used to mount the ReRAM device, the ReRAM device comprising: an array comprising a plurality of ReRAM cells arranged in a matrix of at least one column and at least one row; a bit-line decoder communicatively connected to the ReRAM array; a word-line driver communicatively connected to the ReRAM array; a SMT reference resistance bank comprising at least one SMT reference resistances, wherein each SMT reference resistance of the at least one SMT reference resistances is higher than a pre-SMT reference resistance; and a control logic configured to control the bit-line decoder, the word-line driver and the SMT reference resistance bank; wherein the control logic selects a first SMT reference resistance from the SMT reference resistance bank when read of the ReRAM device is performed after SMT mounting of the ReRAM device on a printed circuit board (PCB).

### BRIEF DESCRIPTION OF THE DRAWINGS

The subject matter disclosed herein is particularly pointed out and distinctly claimed in the claims at the conclusion of the specification. The foregoing and other objects, features, and advantages of the disclosed embodiments will be apparent from the following detailed description taken in conjunction with the accompanying drawings.

FIG. 1 is a graph depicting the impact of a surface mount technology (SMT) when mounting a resistive random-access memory (ReRAM) device to a printed circuit board (PCB).

FIG. 2 is a manufacturing flow to mitigate an adverse impact of SMT reflow on a ReRAM device according to an embodiment.

FIG. 3 is a graph showing improvement in bit error rate as a result of using the manufacturing flow described in FIG. 2.

FIG. 4 is a graph showing the advantages of the manufacturing flow performed according to an embodiment.

FIG. 5 is a system for mitigation of the adverse impact of SMT on a ReRAM device according to an embodiment.

FIG. 6 is a block diagram of a ReRAM device equipped with SMT reference resistances according to an embodiment.

### DETAILED DESCRIPTION

It is important to note that the embodiments disclosed herein are only examples of the many advantageous uses of the innovative teachings herein. In general, statements made in the specification of the present application do not necessarily limit any of the various claims. Moreover, some statements may apply to some inventive features but not to others. In general, unless otherwise indicated, singular elements may be in plural and vice versa with no loss of generality. In the drawings, like numerals refer to like parts through several views.

As surface mount technology (SMT) process can have a significant impact on the bit error rate (BER) of resistive random-access memory (ReRAM) devices, there is provided a manufacturing process to mitigate the impact. Specifically, when mounting a ReRAM device on a printed circuit board (PCB) using SMT, the BER increases. Accordingly, a method adds a step of reading the ReRAM device's cells with an optimized resistive threshold value that improves the BER, the optimized resistance selected from a SMT reference resistance bank. Thereafter, also disclosed are a ReRAM device and a system for BER degradation mitigation upon mounting of a ReRAM device on a PCB using SMT. A refresh cycle of the ReRAM devices is performed and nominal resistive value for reading is sued thereafter. Adapting the resistive threshold for reading post-SMT reduces BER enough for an error correction mechanism to salvage the chip because of the BER's less dramatic degradation.

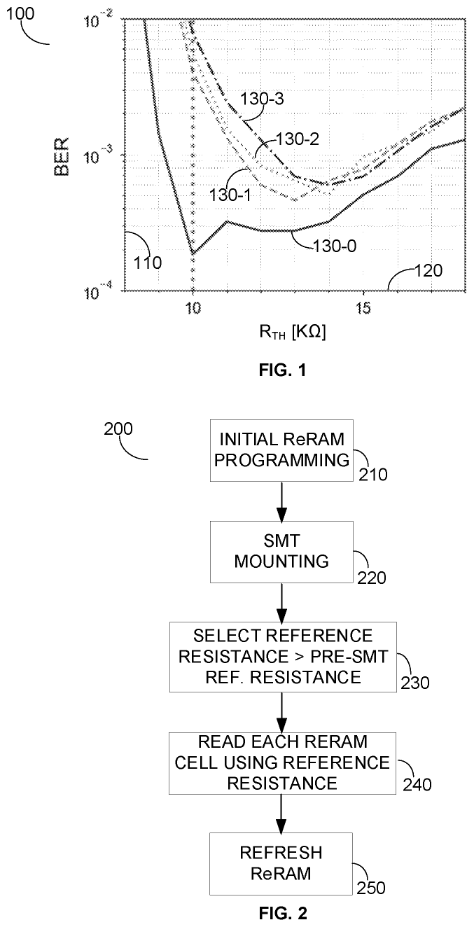

FIG. 1 is an example graph 100 depicting the impact of an SMT reflow when mounting a ReRAM device to a PCB. The vertical axis 110 of the graph 100 denotes the BER, where a lower BER is better and thus, less errors in data stored in the ReRAM device. The scale of the vertical axis 110 is logarithmic. The horizontal axis 120 denotes the ReRAM cell filament threshold resistance (R_{TH}) in kilo Ohms [KΩ]. The initial curve 130-0 is the bit error rate (BER) as a function of R_{TH} prior to the SMT process. Each of the curves 130-1, 130-2, and 130-3, corresponds to additional SMT reflows, 1, 2, and 3 respectively, and show a drastic degradation of the BER as a function of R_{TH} that degrades towards a higher resistance. Such degradation is problematic because the low-resistance state (LRS) of the ReRAM cell degrades more than the high-resistance state (HRS) of the ReRAM cell. This leads to a higher BER as it is more difficult to differentiate between LRS and HRS. The BER greatly degrades since LRS fails more than HRS.

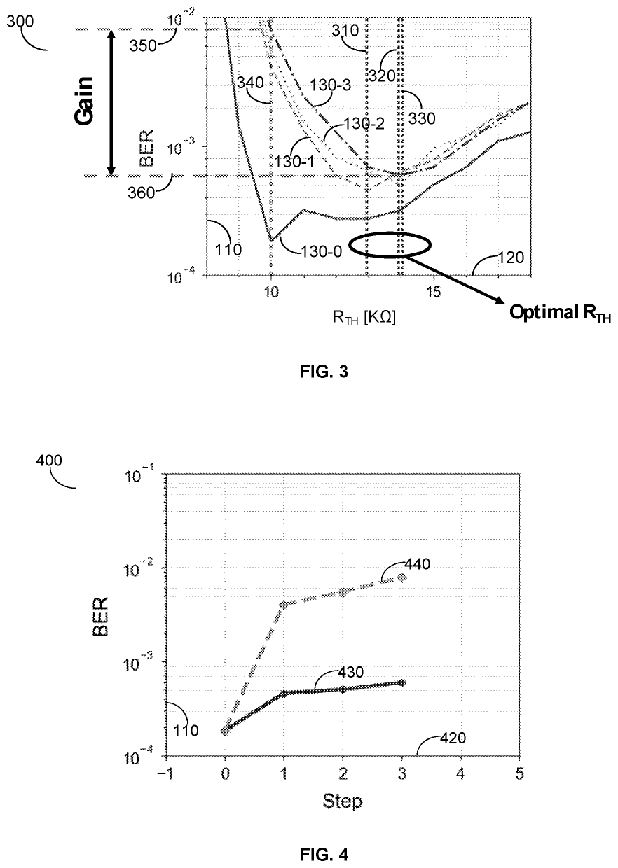

FIG. 2 depicts an example manufacturing flow 200 to mitigate the adverse impact of SMT on a ReRAM device according to an embodiment. As in a typical manufacturing using SMT, initial programming 210 of the ReRAM device, and mounting 220 on a PCB using SMT, is performed. However, as noted, the SMT mounting 220 of the ReRAM device on a PCB results in an increased BER which is undesirable. The increased BER is especially undesired as error correction algorithms of the ReRAM device may be limited in or unable to bring the ReRAM device to an acceptable BER with error correction. Therefore, according to an embodiment, a read of each ReRAM cell of the ReRAM device is read with reference to one or more SMT reference resistances, as further shown in FIGS. 3 and 6 herein.

Subsequent to SMT mounting 220, at 230, instead of using the pre-SMT resistance value as a reference, an SMT reference resistance is selected, which is used while SMT mounting 220 takes place. Now, at 240, each ReRAM cell of the ReRAM device is read using the selected SMT reference resistance. In an embodiment the SMT reference resistance is selected, based on the number of SMT reflows, from a plurality of SMT reference resistances, each of which has a resistance greater than the pre-SMT reference resistance. At 250, a refresh of the ReRAM takes place. The ReRAM device mounted on the PCB using SMT according to the disclosed method may be used with optimal R_{TH} values and with a lesser effect on the BER as shown herein. By using standard switching parameters, the ReRAM device may be brought back to its pre-SMT distributions and provide an expected BER level. It should be understood that the refresh of a ReRAM is a process of restoring the ReRAM cells to their initial preprogrammed state.

Reference is now made to FIG. 3 that depicts an example graph 300 showing a BER improvement by using the manufacturing flow described in FIG. 2. The impact of the SMT mounting process is as shown in curves 130-1, 130-2 and 130-3, that each displays a shift in the optimal R_{TH} as a result of the SMT reflow. The changed optimal R_{TH} for curves 130-1, 130-2, and 130-3 are shown as lines 310, 320, and 330, respectively. The ReRAM cell, rather than exhibiting the optimal R_{TH} shown for curve 130-0 at 10 KΩ 340, the optimal R_{TH} shifts to a different and higher resistance. To this end, after SMT reflow, the BER for the initial R_{TH} may be as high as 10⁻² 350 as shown in curve 130-3 (i.e., after 3 reflows of SMT) instead of closer to a BER of 10⁻⁴ shown in curve 130-0 at the intersection with line 340. To the left of the line 340, the resistance curve 130-0 is considered the LRS range, i.e., lower resistance, while the right of the line 340 is considered the HRS range of the resistance curve 130-0, i.e., higher resistance.

However, if a different R_{TH} is used, for example, optimal R_{TH} for the curves 130-1, 130-2, or 130-3 at the intersection with lines 310, 320, and 330 respectively, then the BER may be minimized. The BER is reduced below 10⁻³ at the respective optimal R_{TH} values for all three curves (shown as at the intersection of lines 310, 320, and 330 with curves 130-1, 130-2 and 130-3 respectively) compared to the BER of 10⁻² at the initial R_{TH} of 10 KΩ 340. Similar to the resistance curve 130-0, for the curves 130-1, 130-2, or 130-3, left of the optimal R_{TH} lines 310, 320, and 330, respectively, are considered the LRS range, while right of the lines 310, 320, and 330, respectively, are considered the HRS range. As shown in graph 300, an improvement in BER is achieved that improves from about a BER of 10⁻² 350 to a BER of better than (i.e., lower than) 10⁻³, which is an order of magnitude improvement of BER. The BER improvement may allow error correction algorithms of the ReRAM device to overcome the BER degradation as a result of SMT reflow and present a functional ReRAM device post SMT mounting. That is, at a BER level shown at 350, a ReRAM device would be considered failed, while at a BER level shown at 360 a ReRAM device would be considered functional, albeit requiring some error correction. It should be noted that using the changed optimal R_{TH} after SMT reflow reduces BER level to be within the acceptable functional range and overcomes adverse effects of SMT mounting detected in known arts.

FIG. 4 is an example graph 400 showing the advantages of the manufacturing flow performed according to an embodiment. The graph 400 has a vertical axis 110 that is a logarithmic scale of BER. The graph 400 has further a horizontal axis 420 depicting the number of steps that show the impact of SMT mounting steps on the BER. Specifically, the number of steps corresponds to the number of SMT reflows, which means that a thermal budget gradually increases. Curve 430 shows the effect of optimized R_{TH} on a ReRAM mounted using SMT according to an embodiment, while curve 440 shows the impact of using an initial R_{TH} (or a pre-SMT resistance) on a ReRAM mounted using SMT without changing the R_{TH}. Step “0” is the step prior to the SMT mounting and hence, for both cases, the BER of the ReRAM device is the same, close to 10⁻⁴. However, once the SMT mounting takes place, there is a significant difference between the BER shown for SMT mounting that use the initial R_{TH}, with BER ranging between 6*10⁻³ to 10⁻² (see curve 440), versus BER ranging between 6*10⁻³ to 5*10⁻³ for the SMT mounting process according to embodiments presented herein.

Returning to FIG. 2, it is noted that different R_{TH} values are utilized to read at (or after) the SMT mounting step 220. By adjusting these resistance thresholds, it is possible to distinguish between different resistance states, i.e., HRS and LRS, and accurately read the stored data. As noted above, the adjusted R_{TH} is further used, according to an embodiment, to mitigate the impact of the SMT mounting on the ReRAM device. Before reading a ReRAM device, appropriate voltage levels are set for the read operation. The voltage levels depend on the specific characteristics of the ReRAM technology, the device design, and the optimized R_{TH} values that are targeted. The read schemes may be, for example, current sensing or voltage sensing. Regardless of the chosen scheme, it allows for the determination of R_{TH} values for the LRS and HRS of the ReRAM device. As noted, these resistance thresholds help classify the resistance levels as high or low resistance states, corresponding to different data states (e.g., “1” or “0”). It should be noted that, according to an embodiment, multiple R_{TH} values that are greater than the initial R_{TH} value may be used in sequence in order to mitigate the effects of the SMT mounting.

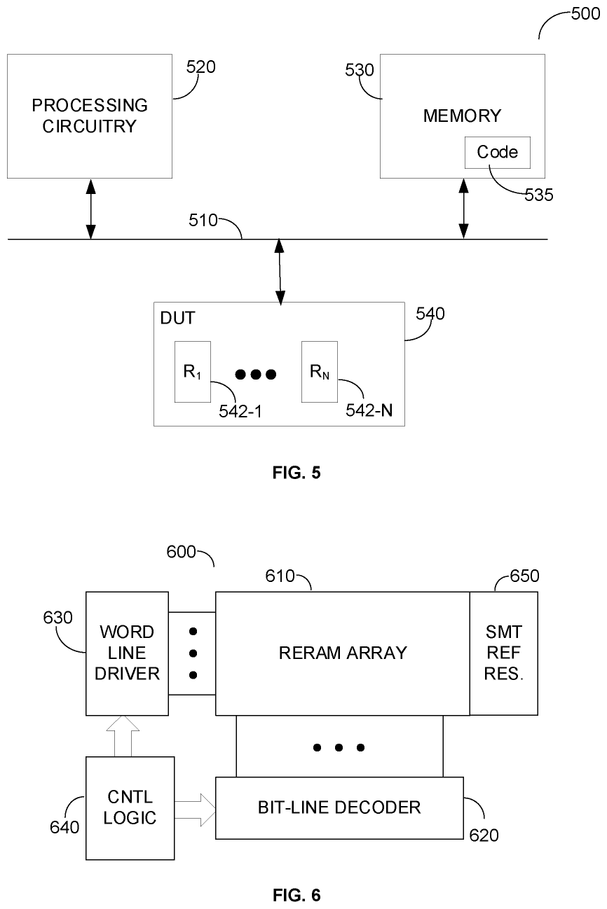

FIG. 5 is an example system 500 for mitigation of the adverse impact of SMT on a ReRAM device according to an embodiment. The system 500 comprises a processing circuitry 520 that is communicatively connected to a connectivity network 510. The processing circuitry 520 may be realized as one or more hardware components and circuits. For example, and without limitation, illustrative types of hardware logic components that can be used include field-programmable gate arrays (FPGAs), application-specific integrated circuits (ASICs), application-specific standard products (ASSPs), system-on-a-chip systems (SOCs), general-purpose microprocessors, microcontrollers, digital signal processors (DSPs), and the like, whether general purpose or specialized processors, or any other hardware logic components that can perform calculations or other manipulations of data and/or information, as well as any permissible combinations thereof.

The connectivity network 510 may be an internal bus, external bus, a network, and other connectivity schemes, and any permissible combinations thereof. In an embodiment the system 500, or components thereof, may be implemented as part of a robotic system designed for performing the SMT process for attachment of devices, for example but without limitation, ReRAM devices, to a PCB.

To the connectivity network 510 there is further communicatively connected a memory 530. The memory 530 may comprise volatile memory, for example but not by way of limitation, static random-access memory (SRAM), as well as non-volatile memory, for example but not by way of limitation, read only memory (ROM) and Flash memory, as well as other like memories and any permissible combinations thereof. The memory 530 may further comprise a dedicated area for code memory 535. Therein shall be stored instructions that, when executed by the processing circuitry 520, perform, for example but not by way of limitation, the methods of embodiments described herein.

To perform the SMT impact mitigation described herein, a device under test (DUT) 540 is connected to the connectivity network 510. The DUT 540 may be the PCB described herein in greater detail. The DUT 540, among others, would have SMT mounted ReRAM devices 542, for example ReRAM devices R₁ 542-1 through R_{N} 542-N, where ‘N’ is an integer equal to or greater than ‘1’. The DUT 540 is connected to the connectivity network 510 subsequent to the mounting of the ReRAM devices 542 with the aim of performing the steps 230 and 240 described in greater detail with respect to FIG. 2, and which are therefore not repeated here. The instructions of steps 230 and 240 are coded in memory 535 and executed by the processing circuitry 520. These instructions are configured to change the R_{TH} as described herein for the mitigation reading at 240. Thereafter, at 250 the refresh of the ReRAM cells of the ReRAM devices 542 takes place.

FIG. 6 is a block diagram of a ReRAM device 600 equipped with SMT reference resistances according to an embodiment. The ReRAM device 600 comprises a ReRAM array 610. A ReRAM array, for example the ReRAM array 610, comprises a matrix of ReRAM cells (not shown) organized in rows and columns. In an embodiment the columns are controlled by a bit-line decoder 620 while the rows are controlled by a word-line driver 630. During the operation of the ReRAM array 610, the bit-line decoder 620 and the word-line driver 630 are controlled by the control logic 640. The control logic 640 is designed to allow for the various operations of the ReRAM device 600, including reading the ReRAM device 600, performing SET and RESET operation of the ReRAM device 600, as well as performing refresh of the ReRAM array 610 as may be necessary at initialization of the ReRAM device 600.

According to an embodiment, a SMT reference resistance bank 650 contains therein one or more SMT reference resistances. Each of the one or more SMT reference resistances has a resistance value which is higher than the pre-SMT resistance of a resistive filament of a ReRAM cell of the ReRAM device 600 (see, for example, FIG. 3). Under the control of the control logic 640, a SMT reference resistance from the SMT reference resistance bank 650 is selected from the one or more SMT reference resistances. The selected SMT reference resistance is used, according to an embodiment, to read the ReRAM cells of the ReRAM array 610 during the SMT process and as further explained herein. It should be appreciated that each of the ReRAM devices 542 of FIG. 5 may be the ReRAM device 600. The SMT reference resistance bank 650 may be implemented using, for example, transistors, polysilicon, and the like.

The various embodiments disclosed herein can be implemented as hardware, firmware, software, or any combination thereof. Moreover, the software is preferably implemented as an application program tangibly embodied on a program storage unit or computer readable medium consisting of parts, or of certain devices and/or a combination of devices. The application program may be uploaded to, and executed by, a machine comprising any suitable architecture. Preferably, the machine is implemented on a computer platform having hardware such as one or more central processing units (“CPUs”), a memory, and input/output interfaces. The computer platform may also include an operating system and microinstruction code. The various processes and functions described herein may be either part of the microinstruction code or part of the application program, or any combination thereof, which may be executed by a CPU, whether or not such a computer or processor is explicitly shown. In addition, various other peripheral units may be connected to the computer platform such as an additional data storage unit and a printing unit. Furthermore, a non-transitory computer-readable medium is any computer-readable medium except for a transitory propagating signal.

All examples and conditional language recited herein are intended for pedagogical purposes to aid the reader in understanding the principles of the disclosed embodiment and the concepts contributed by the inventor to furthering the art and are to be construed as being without limitation to such specifically recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

It should be understood that any reference to an element herein using a designation such as “first,” “second,” and so forth does not generally limit the quantity or order of those elements. Rather, these designations are generally used herein as a convenient method of distinguishing between two or more elements or instances of an element. Thus, a reference to first and second elements does not mean that only two elements may be employed there or that the first element must precede the second element in some manner. Also, unless stated otherwise, a set of elements comprises one or more elements.

As used herein, the phrase “at least one of” followed by a listing of items means that any of the listed items can be utilized individually, or any combination of two or more of the listed items can be utilized. For example, if a system is described as including “at least one of A, B, and C,” the system can include A alone; B alone; C alone; 2A; 2B; 2C; 3A; A and B in combination; B and C in combination; A and C in combination; A, B, and C in combination; 2A and C in combination; A, 3B, and 2C in combination; and the like.

What is claimed is:

1. A method for mitigation of bit error rate (BER) increase from surface mount technology (SMT) used to mount a resistive random-access memory (ReRAM) device onto a printed circuit board (PCB), comprising:
mounting the ReRAM device to the PCB using the SMT, wherein the ReRAM device includes a plurality of ReRAM cells;
selecting an SMT reference resistance of the ReRAM device, wherein the SMT reference resistance is higher than a pre-SMT reference resistance; and
performing at least one read operation on at least one of the plurality of ReRAM cells using the selected SMT reference resistance as a reference.

2. The method of claim 1, further comprising:
performing a refresh of the ReRAM cells.

3. The method of claim 1, further comprising:
performing an initialization of the ReRAM cells.

4. The method of claim 1, wherein selecting the SMT reference resistance further comprises:
selecting, from a plurality of SMT reference resistances, the SMT reference resistance, wherein each SMT reference resistance of the plurality of SMT reference resistances is higher than the pre-SMT reference resistance.

5. The method of claim 4, wherein each SMT reference resistance of the plurality of SMT reference resistances has a different resistance.

6. The method of claim 2, wherein performing the refresh of the ReRAM cells further comprises:
using standard switching parameters to return the ReRAM cells to pre-SMT distributions.

7. A non-transitory computer readable medium having stored thereon instructions for causing a processing circuitry to execute a process for mitigation of bit error rate (BER) increase from surface mount technology (SMT) used to mount a resistive random-access memory (ReRAM) device onto a printed circuit board (PCB), the process comprising:
mounting the ReRAM device to the PCB using the SMT, wherein the ReRAM device comprises a plurality of ReRAM cells;
selecting an SMT reference resistance of the ReRAM device, wherein the SMT reference resistance is higher than a pre-SMT reference resistance; and
performing at least one read operation on at least one of the plurality of ReRAM cells using the selected SMT reference resistance as a reference.

8. The non-transitory computer readable medium of claim 7, the process further comprising:
performing a refresh of the ReRAM cells.

9. The non-transitory computer readable medium of claim 7, the process further comprising:
performing an initialization of the ReRAM cells.

10. The non-transitory computer readable medium of claim 7, wherein selecting a SMT reference resistance comprises:
selecting from a plurality of SMT reference resistances, the SMT reference resistance, wherein each SMT reference resistance of the plurality of SMT reference resistances is higher than a pre-SMT reference resistance.

11. The non-transitory computer readable medium of claim 10, wherein each SMT reference resistance of the plurality of SMT reference resistances has a different resistance.

12. The non-transitory computer readable medium of claim 8, wherein performing the refresh of the ReRAM cells further comprises:
using standard switching parameters to return the ReRAM cells to pre-SMT distributions.

13. A system for mitigation of bit error rate (BER) increase from surface mount technology (SMT) used to mount at least one resistive random-access memory (ReRAM) device onto a printed circuit board (PCB), the system comprising:
a connectivity network;
a processing circuitry communicatively connected to the connectivity network; and
a memory, the memory containing instructions that, when executed by the processing circuitry, configure the system to:
mount the ReRAM device to the PCB using the SMT wherein the ReRAM device comprises a plurality of ReRAM cells;
select a SMT reference resistance of the ReRAM device, wherein the SMT reference resistance is higher than a pre-SMT reference resistance; and
perform at least one read operation on at least one of the plurality of ReRAM cells using the selected SMT reference resistance as a reference.

14. The system of claim 13, wherein the system is further configured to perform a refresh of the ReRAM cells.

15. The system of claim 13, wherein the system is further configured to perform an initialization of the ReRAM cells.

16. The system of claim 13, wherein the system is further configured to select, from a plurality of SMT reference resistances, the SMT reference resistance, wherein each SMT reference resistance of the plurality of SMT reference resistances is higher than the pre-SMT reference resistance.

17. The system of claim 16, wherein each SMT reference resistance of the plurality of SMT reference resistances has a different resistance.

18. The system of claim 14, wherein the system is further configured to use standard switching parameters to return the ReRAM cells to pre-SMT distributions.

19. The system of claim 13, wherein the processing circuitry comprises at least one of: field-programmable gate array (FPGA), application-specific integrated circuit (ASIC), application-specific standard product (ASSP), system-on-a-chip system (SOC), general-purpose microprocessor, microcontroller, digital signal processor (DSP), and hardware logic components.

20. A resistive random-access memory (ReRAM) device for mitigation of bit error rate (BER) increase from surface mount technology (SMT) used to mount the ReRAM device, the ReRAM device comprising:
a ReRAM array comprising a plurality of ReRAM cells arranged in a matrix of at least one column and at least one row;
a bit-line decoder communicatively connected to the ReRAM array;
a word-line driver communicatively connected to the ReRAM array;
a SMT reference resistance bank comprising at least one SMT reference resistance, wherein each SMT reference resistance of the at least one SMT reference resistance is higher than a pre-SMT reference resistance;
a control logic configured to control the bit-line decoder, the word-line driver, and the SMT reference resistance bank; and
wherein the control logic selects a first SMT reference resistance from the SMT reference resistance bank when read of the ReRAM device is performed after a SMT mounting of the ReRAM device on a printed circuit board (PCB).

21. The ReRAM device of claim 20, wherein the control logic is further configured to perform at least one read operation on the plurality of ReRAM cells using the selected first SMT reference resistance as a reference.

22. The ReRAM device of claim 20, wherein the control logic is further configured to perform a refresh of the ReRAM cells subsequent to the SMT mounting of the ReRAM device on the PCB.

23. The ReRAM device of claim 20, wherein each SMT reference resistance of the at least one SMT reference resistance has a different resistance.
